(19) United States
(12) Patent Application Publication
(10) Pub. No.: US 2026/0318999 A1
(43) Pub. Date: Oct. 15, 2026

(54) BATTERY DIAGNOSIS APPARATUS AND METHOD

(71) Applicant: LG ENERGY SOLUTION, LTD., Seoul (KR)

(72) Inventors: Seon-Ho PAK, Daejeon (KR); Hee-Seok JEONG, Daejeon (KR); Yoon-Jung BAE, Daejeon (KR)

(73) Assignee: LG ENERGY SOLUTION, LTD., Seoul (KR)

(21) Appl. No.: 19/685,784

(22) Filed: May 22, 2026

Related U.S. Application Data
(63) Continuation of application No. PCT/KR2025/018762, filed on Nov. 13, 2025.

(30) Foreign Application Priority Data
Nov. 22, 2024 (KR) 10-2024-0168345

(51) Int. Cl. G01R 31/3835; G01R 31/367; H01M 10/42

(52) U.S. Cl. CPC G01R 31/3835; G01R 31/367; H01M 10/4285

(57) ABSTRACT

A battery diagnosis apparatus according to an embodiment of the present disclosure includes a profile obtaining unit configured to obtain a voltage profile for a voltage of a battery measured according to a preset measurement cycle; and a control unit configured to determine a first voltage section and a second voltage section from the plurality of voltage profiles obtained by the profile obtaining unit in a plurality of cycles, determine a first voltage number of voltages included in the first voltage section and a second voltage number of voltages included in the second voltage section in each of the plurality of voltage profiles, and diagnose a state of the battery based on a first ratio of the plurality of first voltage numbers and a second ratio of the plurality of second voltage numbers.

### TECHNICAL FIELD

This application is based on and claims priority from Korean Patent Application No. 10-2024-0168345, filed on Nov. 22, 2024, with the Korean Intellectual Property Office, the disclosure of which is incorporated herein in its entirety by reference.

The present disclosure relates to a battery diagnosis apparatus and method for diagnosing a state of a battery.

### BACKGROUND ART

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Batteries commercially available at present include nickel-cadmium batteries, nickel hydrogen batteries, nickel-zinc batteries, lithium batteries and the like. Among them, the lithium batteries are in the limelight since they have almost no memory effect compared to nickel-based batteries and also have very low self-discharging rate and high energy density.

While much research is being conducted on these batteries to increase capacity and density, improving their lifespan and safety is also crucial. To enhance battery safety, technology is required to accurately diagnose the state of a battery.

### DISCLOSURE

### Technical Problem

The present disclosure is directed to providing a battery diagnosis apparatus and method for more accurately estimating a current state of a battery.

These and other objects and advantages of the present disclosure may be understood from the following detailed description and will become more fully apparent from the exemplary embodiments of the present disclosure. Also, it will be easily understood that the objects and advantages of the present disclosure may be realized by the means shown in the appended claims and combinations thereof.

### Technical Solution

A battery diagnosis apparatus according to one aspect of the present disclosure may comprise: a profile obtaining unit configured to obtain a voltage profile for a voltage of a battery measured according to a preset measurement cycle; and a control unit configured to determine a first voltage section and a second voltage section from the plurality of voltage profiles obtained by the profile obtaining unit in a plurality of cycles, determine a first voltage number of voltages included in the first voltage section and a second voltage number of voltages included in the second voltage section in each of the plurality of voltage profiles, and diagnose a state of the battery based on a first ratio of the plurality of first voltage numbers and a second ratio of the plurality of second voltage numbers.

The control unit may be configured to compare the first ratio with the second ratio and diagnose the state of the battery as a normal state, a warning state, or an abnormal state based on the comparison result.

The control unit may be configured to diagnose the state of the battery as the normal state when the first ratio is greater than the second ratio.

When the first ratio is lower than or equal to the second ratio, the control unit may be configured to compare a first change rate of the first ratio and a second change rate of the second ratio with a preset reference change rate and diagnose the state of the battery as the warning state or the abnormal state based on the comparison result.

The control unit may be configured to diagnose the state of the battery as the warning state when the first change rate and the second change rate are lower than or equal to the reference change rate.

The control unit may be configured to diagnose the state of the battery as the abnormal state when the first change rate and the second change rate exceed the reference change rate.

The control unit may be configured to set a reference voltage section in the plurality of voltage profiles and classify the reference voltage section into the first voltage section and the second voltage section.

The control unit may be configured to classify the reference voltage section into a low voltage section and a high voltage section, set the low voltage section as the first voltage section, and set the high voltage section as the second voltage section.

The control unit may be configured to exclude a voltage profile, which does not include a voltage for at least a part of the reference voltage section, among the plurality of voltage profiles from diagnosing the state of the battery.

The control unit may be configured to set a preset voltage section or a common voltage section of the plurality of voltage profiles as the reference voltage section.

The control unit may be configured to set the common voltage section as the reference voltage section when the common voltage section of the plurality of voltage profiles exists.

The control unit may be configured to set the preset voltage section as the reference voltage section when the common voltage section does not exist.

The control unit may be configured to calculate a first ratio for each of the plurality of first voltage numbers based on a first reference number, and calculate a second ratio for each of the plurality of second voltage numbers based on a second reference number.

The control unit may be configured to set a first voltage number for an initial cycle among the plurality of cycles as the first reference number, and set a second voltage number for the initial cycle as the second reference number.

The control unit may be configured to diagnose the state of the battery based on a cycle that is greater than or equal to a preset reference cycle among the plurality of cycles.

A battery pack according to another aspect of the present disclosure comprises the battery diagnosis apparatus according to one aspect of the present disclosure.

A battery diagnosis method according to still another aspect of the present disclosure may comprise: a profile obtaining step of obtaining a voltage profile for a voltage of a battery measured according to a preset measurement cycle; a voltage section determining step of determining a first voltage section and a second voltage section from the plurality of voltage profiles obtained in the voltage profile obtaining step; a voltage number determining step of determining a first voltage number of voltages included in the first voltage section and a second voltage number of voltages included in the second voltage section in each of the plurality of voltage profiles; and a diagnosing step of diagnosing a state of the battery based on a first ratio of the plurality of first voltage numbers and a second ratio of the plurality of second voltage numbers.

A computer-readable recording medium according to still another aspect of the present disclosure may store a computer program for executing a battery diagnosis method according to one aspect of the present disclosure.

### Advantageous Effects

According to one aspect of the present disclosure, the battery diagnosis apparatus may diagnose the state of the battery by considering changes in the state or performance of the battery by considering the variation pattern of the number of voltages measured in a predetermined voltage section.

Furthermore, since variation pattern analysis is relatively easy with the battery diagnosis apparatus, battery diagnosis may be performed quickly and system resources required for battery diagnosis may be saved. In addition, since the method of counting the number of measured voltages is applied, it has the advantage of being more robust to noise than the method of diagnosing the state of the battery using measured voltage values.

The effects of the present disclosure are not limited to the effects mentioned above, and other effects not mentioned will be clearly understood by those skilled in the art from the description of the claims.

### DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a diagram schematically illustrating a battery diagnosis apparatus according to an embodiment of the present disclosure.

FIG. 2 is a schematic diagram illustrating a voltage profile according to an embodiment of the present disclosure.

FIG. 3 to FIG. 6 are schematic diagrams illustrating a first ratio and a second ratio of each cycle for the first to fourth batteries.

FIG. 7 is a drawing schematically illustrating a battery pack according to another embodiment of the present disclosure.

FIG. 8 is a drawing schematically illustrating a battery diagnosis method according to still another embodiment of the present disclosure.

### BEST MODE

Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a most preferred example for the purpose of illustrations only, not intended to limit the scope of the disclosure, so it should be understood that other equivalents and modifications could be made thereto without departing from the scope of the disclosure.

In addition, when explaining the present disclosure, if it is judged that the detailed description of the related known structure or function may obscure the main point of the present disclosure, the detailed description will be omitted.

The terms including the ordinal number such as “first”, “second” and the like, may be used to distinguish one element from another among various elements, but not intended to limit the elements by the terms.

Throughout the specification, when a portion is referred to as “comprising” or “including” any element, it means that the portion may include other elements further, without excluding other elements, unless specifically stated otherwise.

In addition, throughout the specification, when a portion is referred to as being “connected” to another portion, it is not limited to the case that they are “directly connected”, but it also includes the case where they are “indirectly connected” with another element being interposed between them.

Hereinafter, a preferred embodiment of the present disclosure will be described in detail with reference to the attached drawings.

FIG. 1 is a diagram schematically illustrating a battery diagnosis apparatus 100 according to an embodiment of the present disclosure.

Referring to FIG. 1, a battery diagnosis apparatus 100 may include a profile obtaining unit 110 and a control unit 120.

Here, the battery refers to an independent cell that has a negative electrode terminal and a positive electrode terminal and is physically separable. As an example, a lithium-ion cell or a lithium polymer cell may be considered a battery. Additionally, the type of battery may be cylindrical type, prismatic type, or pouch type. Additionally, a battery may also mean a battery bank, a battery module, or a battery pack including a plurality of cells connected in series and/or parallel. For convenience of explanation, below, a battery is described as meaning a single independent cell.

The profile obtaining unit 110 may be configured to obtain a voltage profile for the voltage of the battery measured according to a preset measurement cycle.

Specifically, the voltage of the battery may be measured according to a preset measurement cycle. Then, a voltage profile representing voltage changes according to time or voltage changes according to capacity may be generated.

For example, the voltage of the battery may be measured every 0.1 seconds during the charging process. In this case, a voltage profile representing the voltage measured at each measurement time point with an interval of 0.1 seconds during the battery charging process may be generated.

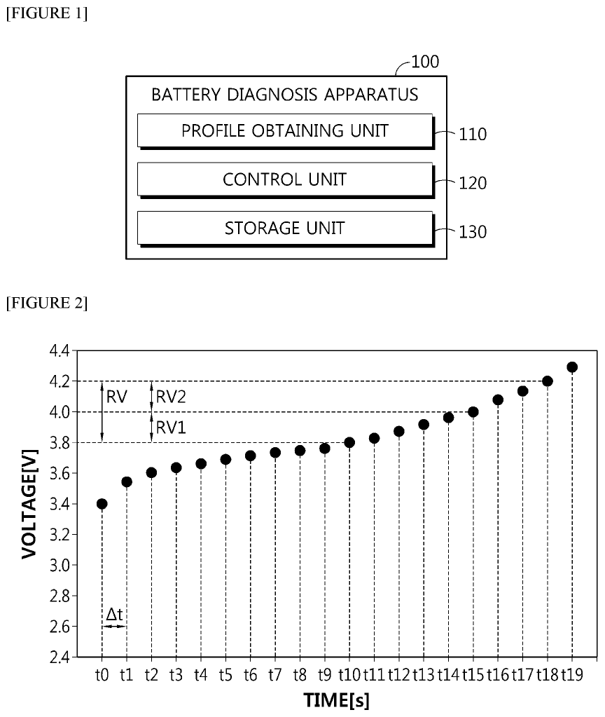

FIG. 2 is a schematic diagram illustrating a voltage profile according to an embodiment of the present disclosure. In the embodiment of FIG. 2, the voltage profile may be expressed as an X-Y graph in which the X-axis is set to time and the Y-axis is set to voltage. However, it should be noted that the voltage profile of FIG. 2 is expressed in the form of a graph only for the convenience of explanation, and there is no limitation on the format in which the voltage profile is expressed as long as a correspondence between the measurement time and the battery voltage is shown.

Specifically, the voltage profile in FIG. 2 is generated during the process of charging the battery voltage from 3.4 V to 4.3 V. Then, the voltage of the battery is measured according to a preset measurement cycle (Δt) from time point t0 to time point t19. That is, during the battery charging process, the voltage of the battery is measured a total of 20 times.

For example, the profile obtaining unit 110 may directly receive a voltage profile from an external source connected by wire and/or wirelessly.

As another example, the profile obtaining unit 110 may receive battery information about the voltage of the battery and the voltage measurement time point. In addition, the profile obtaining unit 110 may generate a voltage profile based on the received battery information. In other words, the profile obtaining unit 110 may obtain a voltage profile by directly generating the voltage profile based on the battery information.

The profile obtaining unit 110 may be connected to communicate with the control unit 120. For example, the profile obtaining unit 110 may be connected to the control unit 120 by wire and/or wirelessly. The profile obtaining unit may transmit the obtained voltage profile to the control unit 120.

The control unit 120 may be configured to determine a first voltage section and a second voltage section from the plurality of voltage profiles obtained by the profile obtaining unit 110 in a plurality of cycles.

Specifically, the control unit 120 may receive a voltage profile corresponding to each of the plurality of cycles from the profile obtaining unit 110. For example, if the profile obtaining unit 110 obtains a voltage profile in each of the first to nth cycles, the control unit 120 may receive a total of n voltage profiles from the profile obtaining unit 110. The control unit 120 may determine a first voltage section and a second voltage section for the n voltage profiles. Preferably, the first voltage section and the second voltage section are voltage sections common to the n voltage profiles.

First, the control unit 120 may determine a reference voltage section for the plurality of voltage profiles. In one embodiment, the reference voltage section may be set based on the voltage section of the plurality of voltage profiles. For example, the reference voltage section may be set as a common voltage section of the plurality of voltage profiles. In another embodiment, the reference voltage section may be preset based on experiments or theories that diagnose the state of the battery. For example, the reference voltage section may be preset to 3.8 V to 4.2 V.

In addition, the control unit 120 may be configured to classify the reference voltage section into a first voltage section and a second voltage section.

Specifically, control unit 120 may be configured to classify the reference voltage section into a low voltage section and a high voltage section. The reference voltage section may be classified into a low voltage section and a high voltage section based on the voltage contained within the section. In addition, control unit 120 may be configured to set the low voltage section as the first voltage section and set the high voltage section as the second voltage section.

For example, assume that the reference voltage section is a voltage section greater than or equal to Va and less than or equal to Vc, and that Vb is included within the reference voltage section. That is, Va is less than Vb, and Vb is less than Vc. The reference voltage section may be classified into a low voltage section (greater than or equal to Va and less than or equal to Vb) and a high voltage section (greater than or equal to Vb and less than or equal to Vc) based on Vb. In addition, the low voltage section may be set as the first voltage section, and the high voltage section may be set as the second voltage section.

In the embodiment of FIG. 2, it is assumed that the reference voltage section RV is set to a voltage section of 3.8 V or more and 4.2 V or less. The control unit 120 may classify the reference voltage section RV into a first voltage section RV1 and a second voltage section RV2 based on 4.0 V. Here, the first voltage section RV1 is a voltage section of 3.8 V or more and 4.0 V or less, and the second voltage section RV2 is a voltage section of 4.0 V or more and 4.2 V or less.

The control unit 120 may be configured to determine a first voltage number of voltages included in the first voltage section and a second voltage number of voltages included in the second voltage section in each of the plurality of voltage profiles.

Specifically, the control unit 120 may determine the first voltage number by counting the number of times the voltage is measured in the first voltage section. In addition, the control unit 120 may determine the second voltage number by counting the number of times the voltage is measured in the second voltage section. For example, if a voltage is measured at the upper limit of the first voltage section (the lower limit of the second voltage section), this voltage may be included in both the first voltage number and the second voltage number.

In the embodiment of FIG. 2, since the number of times the voltage of the battery is measured in the first voltage section RV1 is 6, the control unit 120 may determine the first voltage number as 6. In addition, since the number of times the voltage of the battery is measured in the second low-charge section is 4, the control unit 120 may determine the second voltage number as 4. Here, since the voltage measured at 4.0 V may be included in both the first voltage section RV1 and the second voltage section RV2 at the same time, the first voltage number may be determined as 6, and the second voltage number may be determined as 4.

The control unit 120 may be configured to diagnose the state of the battery based on the first ratio of the plurality of first voltage numbers and the second ratio of the plurality of second voltage numbers.

Specifically, the control unit 120 may be configured to calculate the first ratio for each of the plurality of first voltage numbers based on the first reference number. Here, the control unit 120 may be configured to set the first voltage number for the initial cycle among the plurality of cycles as the first reference number. That is, the control unit 120 may calculate the ratio for the first voltage number of each cycle based on the first voltage number of the initial cycle. For example, it is assumed that there are n first voltage numbers for the initial cycle and m first reference numbers for the kth cycle. The control unit 120 may calculate “m÷n” or “m÷n×100” to calculate the first ratio of the first voltage number for the kth cycle.

Similarly, the control unit 120 may be configured to calculate the second ratio for each of the plurality of second voltage numbers based on the second reference number. The control unit 120 may be configured to set the second voltage number for the initial cycle as the second reference number.

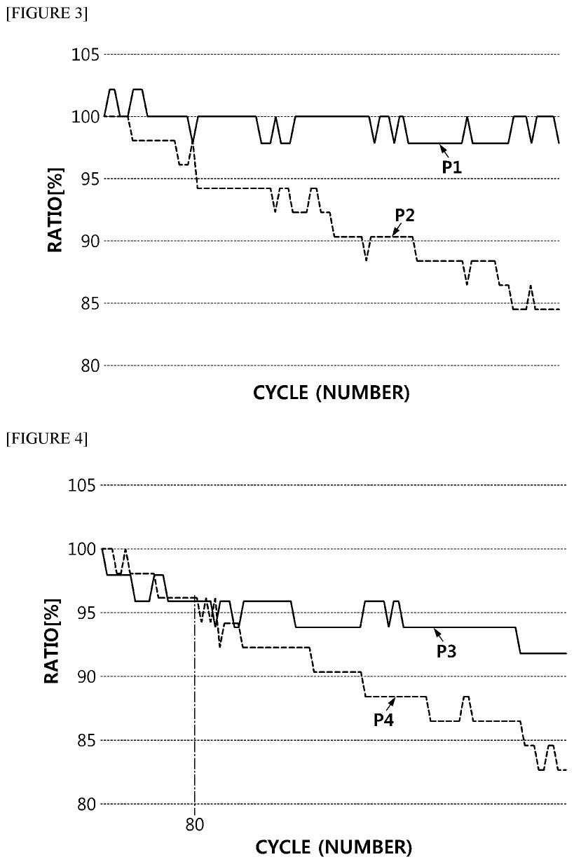

FIG. 3 to FIG. 6 are schematic diagrams illustrating a first ratio and a second ratio of each cycle for the first to fourth batteries.

FIG. 3 is a schematic diagram illustrating the first profile P1 and the second profile P2 for the first battery. Here, the first profile P1 represents the first ratio of the first battery for each cycle. And, the second profile P2 represents the second ratio of the first battery for each cycle. Comparing the first profile P1 and the second profile P2, the first ratio is higher than the second ratio in all cycles. Based on the fact that the first ratio is higher than the second ratio in a plurality of cycles, the control unit 120 may diagnose the state of the first battery as a normal state.

FIG. 4 is a schematic diagram illustrating the third profile P3 and the fourth profile P4 for the second battery. Here, the third profile P3 represents the first ratio of the second battery for each cycle. And, the fourth profile P4 represents the second ratio of the second battery for each cycle. Comparing the third profile P3 and the fourth profile P4, the first ratio tends to be lower than the second ratio in the early cycle (e.g., before the kth cycle), but the first ratio tends to be higher than the second ratio in the subsequent cycle (e.g., after the kth cycle). Based on the fact that the first ratio is higher than the second ratio in the overall cycle (especially, in the cycle after the early cycle), the control unit 120 may diagnose the state of the second battery as a normal state.

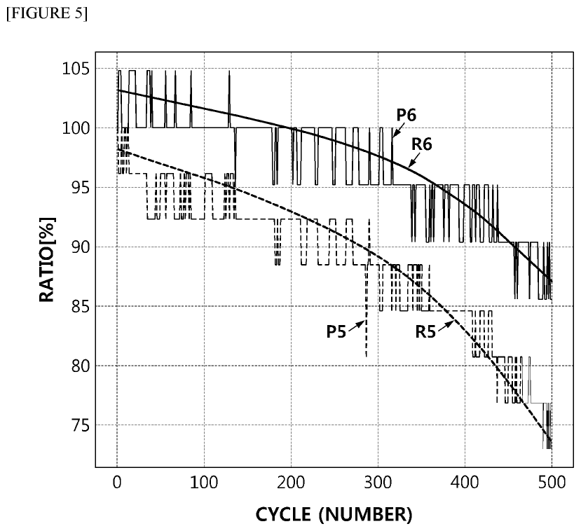

FIG. 5 is a schematic diagram illustrating the fifth profile P5 and sixth profile P6 for the third battery. Here, the fifth profile P5 represents the first ratio of the third battery for each cycle. And, the sixth profile P6 represents the second ratio of the third battery for each cycle. Comparing the fifth profile P5 and sixth profile P6, the first ratio is lower than the second ratio in all cycles. Based on the fact that the first ratio is lower than the second ratio in a plurality of cycles, the control unit 120 may diagnose the state of the third battery as a warning state.

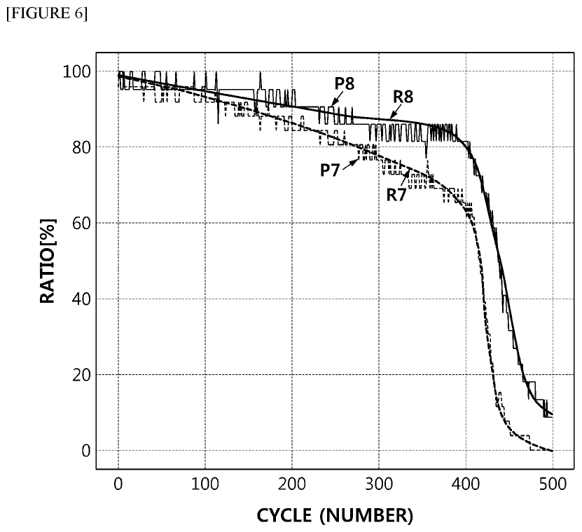

FIG. 6 is a schematic diagram illustrating the seventh profile P7 and the eighth profile for the fourth battery. Here, the seventh profile P7 represents the first ratio of the fourth battery for each cycle. And, the eighth profile represents the second ratio of the fourth battery for each cycle. Comparing the seventh profile P7 and the eighth profile, the first ratio is lower than the second ratio in all cycles. In particular, the first ratio per cycle and the second ratio per cycle tend to decrease rapidly around 400 cycles. Based on the fact that the first ratio is lower than the second ratio in a plurality of cycles and the first ratio for each cycle and the second ratio for each cycle decrease rapidly, the control unit 120 may diagnose the state of the fourth battery as an abnormal state.

The battery diagnosis apparatus 100 according to an embodiment of the present disclosure may diagnose the state of the battery in consideration of a change in the state or performance of the battery by considering a variation pattern of the number of voltages measured in a predetermined voltage section. In addition, according to the battery diagnosis apparatus 100, since variation pattern analysis is relatively easy, battery diagnosis may be performed quickly and system resources required for battery diagnosis may be saved. In addition, since a method of counting the number of measured voltages is applied, it has an advantage of being robust to noise compared to a method of diagnosing a state of the battery using measured voltage values.

Meanwhile, the profile obtaining unit 110 and/or the control unit 120 included in the battery diagnosis apparatus 100 may optionally include processors, application-specific integrated circuits (ASICs), other chipsets, logic circuits, registers, communication modems, data processing devices, etc. known in the art to execute various control logics performed in the present disclosure. Also, when the control logic is implemented as software, the profile obtaining unit 110 and/or the control unit 120 may be implemented as a set of program modules. At this time, the program module may be stored in the memory and executed by the profile obtaining unit 110 and/or the control unit 120. The memory may be inside or outside the profile obtaining unit 110 and/or the control unit 120 and may be connected to the profile obtaining unit 110 and/or the control unit 120 by various well-known means.

In addition, the battery diagnosis apparatus 100 may further include a storage unit 130. The storage unit 130 may store data necessary for operation and function of each component of the battery diagnosis apparatus 100, data generated in the process of performing the operation or function, or the like. The storage unit 130 is not particularly limited in its kind as long as it is a known information storage means that can record, erase, update and read data. As an example, the information storage means may include RAM, flash memory, ROM, EEPROM, registers, and the like. In addition, the storage unit 130 may store program codes in which processes executable by each component of the battery diagnosis apparatus 100 are defined.

For example, the storage unit 130 may store the voltage profile obtained by the profile obtaining unit 110. The control unit 120 may also access the storage unit 130 to obtain the voltage profile.

Below, an embodiment in which control unit 120 diagnoses the state of a battery is described in more detail.

The control unit 120 may be configured to compare the first ratio and the second ratio. Specifically, the control unit 120 may compare the first ratio and the second ratio for each cycle. In addition, the control unit 120 may be configured to diagnose the state of the battery as a normal state, a warning state, or an abnormal state based on the comparison result.

In one embodiment, the control unit 120 may be configured to diagnose the state of the battery as a normal state if the first ratio is greater than the second ratio.

Specifically, the first voltage section is a section more influenced by the negative electrode than the second voltage section, and the second voltage section is a section more influenced by the positive electrode than the first voltage section. Therefore, the first ratio reflects the state of the negative electrode, and the second ratio reflects the state of the positive electrode.

More specifically, as the battery degrades, the capacity of the positive and negative electrodes decreases, and as the capacity of the positive and negative electrodes decreases, the number of voltage measurements according to a predetermined measurement cycle in a certain voltage section decreases.

For example, in the initial state, it is assumed that the voltage is measured 10 times according to a predetermined measurement cycle in a constant voltage section. Later, if the battery degrades and the capacity corresponding to the constant voltage section decreases, the voltage may be measured less than 10 times according to the predetermined measurement cycle. Since charging proceeds faster as the capacity decreases, the number of times the voltage is measured according to the predetermined measurement cycle may decrease. Note that the charge C-rate is the same from the initial state.

That is, the voltage number of the voltage section may vary depending on the degradation state of the positive and negative electrodes. Therefore, among the positive and negative electrodes, the ratio of an electrode with a greater capacity reduction (an electrode with more degradation) may be lower. For example, if the first ratio is greater than the second ratio, this means that the degradation of the negative electrode has occurred less than that of the positive electrode. In another example, if the first ratio is less than the second ratio, this means that the degradation of the negative electrode has occurred more than that of the positive electrode.

Generally, since battery degradation occurs more at the positive electrode than at the negative electrode, in a normally degraded battery, the first ratio may be greater than the second ratio. Therefore, if the first ratio is greater than the second ratio, the control unit 120 determines that the positive electrode has degraded more than the negative electrode, and may diagnose the state of the battery as a normal state.

In the embodiment of FIG. 3, when comparing the first profile P1 and the second profile P2, the first ratio is greater than the second ratio throughout the entire cycle. Therefore, the control unit 120 may diagnose the state of the battery as a normal state.

In another embodiment, the control unit 120 may diagnose the state of the battery as a warning state or an abnormal state if the first ratio is less than or equal to the second ratio.

Preferably, the control unit 120 may diagnose the state of the battery as a warning state or an abnormal state if the first ratio is lower than or equal to the second ratio in a preset number of consecutive cycles. For example, assuming that the preset number of cycles is 10, if the first ratio is lower than or equal to the second ratio in 10 or more consecutive cycles, the control unit 120 may diagnose the state of the battery as a warning state or an abnormal state. That is, the control unit 120 may check whether the first ratio continuously appears lower than or equal to the second ratio in order to reduce the possibility of misdiagnosis due to measurement noise.

As previously explained, battery degradation generally occurs more at the positive electrode than at the negative electrode, in a normally degraded battery, the first ratio is greater than the second ratio. Therefore, a battery with a first ratio lower than the second ratio cannot be considered as being in a normal state, and the control unit 120 may additionally diagnose such a battery.

Specifically, if the first ratio is less than or equal to the second ratio, the control unit 120 may be configured to compare the first change rate of the first ratio and the second change rate of the second ratio with a preset reference change rate.

Here, the first change rate refers to the change rate of the first ratio, and the second change rate refers to the change rate of the second ratio. Specifically, the control unit 120 may set the first change rate by calculating the change rate of the first ratio for each cycle, and may set the second change rate by calculating the change rate of the second ratio for each cycle.

The control unit 120 may generate a regression model of the profile representing the first ratio for each cycle, and set the change rate of the generated regression model as the first change rate. In other words, the first change rate may be said to be an indicator of the rate at which the negative electrode degrades. For example, the control unit 120 may set the value with the largest absolute value among the instantaneous change rates for each cycle of the regression model as the first change rate.

Similarly, the control unit 120 may generate a regression model of the profile representing the second ratio for each cycle, and set the change rate of the generated regression model as the second change rate. In other words, the second change rate may be said to be an indicator of the rate at which the positive electrode degrades. For example, the control unit 120 may set the value with the largest absolute value among the instantaneous change rates for each cycle of the regression model as the second change rate.

In addition, the reference change rate is a preset value that may distinguish the battery state into a warning state and an abnormal state. Preferably, the reference change rate may be preset experimentally or theoretically. Here, the warning state is a state requiring battery inspection, and the abnormal state is an EOL (end of life) state in which battery use is not recommended. In other words, the reference change rate is an indicator that represents a reference speed compared to the degradation rate of the positive and negative electrodes.

The control unit 120 may be configured to compare the first change rate with the reference change rate, compare the second change rate with the reference change rate, and diagnose the state of the battery as a warning state or an abnormal state based on the comparison result.

For example, the control unit 120 may be configured to diagnose the state of the battery as a warning state if the first change rate and the second change rate are lower than or equal to the reference change rate. That is, although the negative electrode of the battery is in a state of being degraded more than the positive electrode, since the speed at which the positive and negative electrodes are degraded is lower than or equal to the reference speed, the control unit 120 may diagnose the state of the battery as a warning state requiring inspection.

In the embodiment of FIG. 5, the control unit 120 may generate a fifth regression model R5 of the fifth profile P5 and set the change rate of the fifth regression model R5 as the first change rate. The control unit 120 may generate a sixth regression model R6 of the sixth profile P6 and set the change rate of the sixth regression model R6 as the second change rate. Since the first change rate and the second change rate are lower than the reference change rate, the control unit 120 may diagnose the state of the third battery as a warning state.

As another example, the control unit 120 may be configured to diagnose the state of the battery as an abnormal state if the first change rate and the second change rate exceed the reference change rate. That is, since the negative electrode of the battery is more degraded than the positive electrode and the speed at which the positive and negative electrodes are degraded exceeds the reference speed, the control unit 120 may diagnose the state of the battery as an abnormal state. Since the degradation of a battery in an EOL state is gradually accelerated, the control unit 120 may diagnose the state of the battery as an abnormal state if the first change rate and the second change rate exceed the reference change rate.

In the embodiment of FIG. 6, the control unit 120 may generate a seventh regression model R7 of the seventh profile P7 and set the change rate of the seventh regression model R7 as the first change rate. The control unit 120 may generate an eighth regression model R8 of the eighth profile and set the change rate of the eighth regression model R8 as the second change rate. Since the change rates of the seventh regression model R7 and the eighth regression model R8 become greater than the reference change rate at approximately 400 cycles, the control unit 120 may diagnose the state of the battery as an abnormal state.

The battery diagnosis apparatus 100 according to an embodiment of the present disclosure has the advantage of being able to diagnose the current state of a battery more accurately by diagnosing the state of the battery in detail. In addition, the battery diagnosis apparatus 100 has the advantage of being able to diagnose the current state of a battery more accurately by considering not only the increase and decrease in the number of voltage measurements (e.g., first and second ratios) but also the rate of increase and decrease in the number of voltage measurements (e.g., first and second change rates).

The control unit 120 may be configured to diagnose the state of the battery based on a cycle greater than or equal to a preset reference cycle among the plurality of cycles.

Generally, when a battery in the beginning of life (BOL) state is charged and discharged, a stabilization reaction occurs in which a solid electrolyte interphase (SEI) layer is formed, the volume of the negative electrode material changes, and the electrochemical characteristics are stabilized. Since the structure of the negative electrode material is gradually stabilized by the stabilization reaction, the first ratio may be affected by the stabilization reaction. In other words, since it is desirable to exclude the voltage number generated when the negative electrode stabilization reaction occurs from diagnosing the state of the battery, the control unit 120 may diagnose the state of the battery based on cycles greater than or equal to the reference cycle.

Here, the reference cycle may be preset to a cycle in which the negative electrode stabilization reaction of the battery does not proceed. For example, typically, the negative electrode stabilization reaction may proceed over approximately 10 to 100 cycles. Assuming that the reference cycle is preset to 101 cycle, the control unit 120 may diagnose the state of the battery based on the first voltage number and the second voltage number for cycles greater than 101 cycle.

For example, in the embodiment of FIG. 4, the reference cycle is preset as the kth cycle. Since the negative electrode stabilization reaction of the battery is active in the cycles prior to the reference cycle, many cycles in which the first ratio is lower than or equal to the second ratio appear. In addition, some cycles in which the first ratio is lower than or equal to the second ratio also appear after the reference cycle. However, since the first ratio does not appear lower than the second ratio in consecutive cycles greater than or equal to the preset number of times and the first ratio is greater than the second ratio, the control unit 120 may diagnose the state of the second battery as a normal state.

The battery diagnosis apparatus 100 according to an embodiment of the present disclosure has the advantage of being able to diagnose the state of a battery more accurately by considering noise resulting from a negative electrode stabilization reaction.

Below, an embodiment in which the control unit 120 sets a reference voltage section is specifically described.

The control unit 120 may be configured to set the reference voltage section in the plurality of voltage profiles.

Specifically, the control unit 120 may be configured to set a preset voltage section or a common voltage section of the plurality of voltage profiles as the reference voltage section.

For example, if the common voltage section of the plurality of voltage profiles exists, the control unit 120 may be configured to set the common voltage section as the reference voltage section. Preferably, the control unit 120 may set the common voltage section in a cycle greater than or equal to the reference cycle as the reference voltage section.

As another example, the control unit 120 may be configured to set the preset voltage section as the reference voltage section if the common voltage section does not exist. In this case, the control unit 120 may be configured to exclude voltage profiles that do not include voltages for at least a part of the reference voltage section among the plurality of voltage profiles from diagnosing the state of the battery.

Specifically, if some voltage profiles do not include a reference voltage section, the first voltage number and second voltage number calculated from these voltage profiles cannot be used to calculate the first ratio and the second ratio. Therefore, the control unit 120 may diagnose the state of the battery based on a voltage profile that includes the reference voltage section among the plurality of voltage profiles.

The battery diagnosis apparatus 100 according to the present disclosure may be applied to a battery management system (BMS). That is, the BMS according to the present disclosure may include the battery diagnosis apparatus 100 described above. In this configuration, at least some of components of the battery diagnosis apparatus 100 may be implemented by supplementing or adding functions of the components included in a conventional BMS. For example, the profile obtaining unit 110, the control unit 120 and the storage unit 130 of the battery diagnosis apparatus 100 may be implemented as components of the BMS.

In addition, the battery diagnosis apparatus 100 according to the present disclosure may be equipped in a battery pack. That is, the battery pack according to the present disclosure may include the above-described battery diagnosis apparatus 100 and at least one battery cell. In addition, the battery pack may further include electrical components (relays, fuses, etc.) and a case, etc.

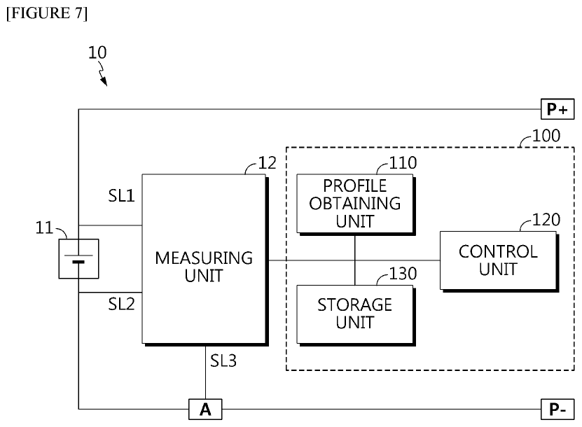

FIG. 7 is a drawing schematically illustrating a battery pack 10 according to another embodiment of the present disclosure.

The positive electrode terminal of the battery 11 may be connected to the positive electrode terminal P+ of the battery pack 10, and the negative electrode terminal of the battery 11 may be connected to the negative electrode terminal P− of the battery pack 10.

The measuring unit 12 may be connected to the first sensing line SL1, the second sensing line SL2 and the third sensing line SL3.

Specifically, the measuring unit 12 may be connected to the positive electrode terminal of the battery 11 through the first sensing line SL1 and connected to the negative electrode terminal of the battery 11 through the second sensing line SL2. The measuring unit 12 may measure the voltage of the battery 11 based on the voltage measured from each of the first sensing line SL1 and the second sensing line SL2. Here, the measuring unit 12 may measure the voltage of the battery 11 according to a preset measurement cycle.

In addition, the measuring unit 12 may be electrically connected to the current measurement unit A through the third sensing line SL3. For example, the current measurement unit A may be a current meter or shunt resistor capable of measuring the charge current and discharge current of the battery 11. The measuring unit 12 may measure the charge current of the battery 11 via the third sensing line SL3 and calculate the charge amount. In addition, the measuring unit 12 may measure the discharge current of the battery 11 via the third sensing line SL3 and calculate the discharge amount.

For example, the profile obtaining unit 110 may directly receive the voltage profile of the battery from the measuring unit 12.

As another example, the profile obtaining unit 110 may receive voltage information about the battery from the measuring unit 12 and generate a voltage profile based on the received voltage information.

An external device may be connected to the positive electrode terminal P+ and the negative electrode terminal P− of the battery pack 10. For example, the external device may be a charging device or a load. In addition, the positive electrode terminal of the battery group 11, the positive electrode terminal P+ of the battery pack 10, the external device, the negative electrode terminal P− of the battery pack 10, and the negative electrode terminal of the battery group 11 may be electrically connected.

The battery pack according to an embodiment of the present disclosure may be included in the vehicle (not shown) such as an electric vehicle (EV) or a hybrid vehicle (HV). Additionally, the battery pack may drive the vehicle by supplying power to the motor through an inverter provided in the vehicle. Here, the battery pack may include the battery diagnosis apparatus 100. That is, the battery diagnosis apparatus 100 may be included in the vehicle. In this case, the battery diagnosis apparatus 100 may be an on-board device included in the vehicle.

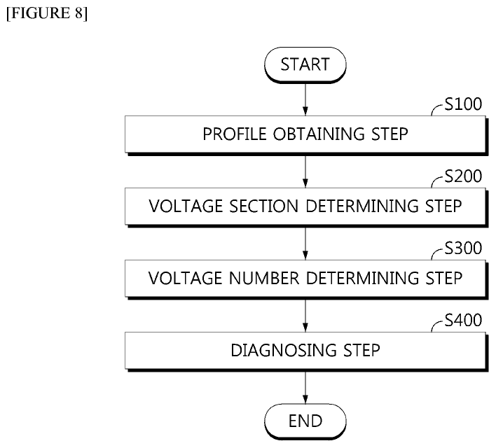

FIG. 8 is a drawing schematically illustrating a battery diagnosis method according to still another embodiment of the present disclosure.

Referring to FIG. 8, the battery diagnosis method may include a profile obtaining step (S100), a voltage section determining step (S200), a voltage number determining step (S300), and a diagnosing step (S400).

Preferably, each step of the battery diagnosis method may be performed by the battery diagnosis apparatus 100. Hereinafter, for convenience of explanation, the content overlapping with the previously described content will be briefly described or omitted.

The profile obtaining step (S100) is a step of obtaining a voltage profile for a voltage of a battery measured according to a preset measurement cycle, and may be performed by the profile obtaining unit 110.

For example, the profile obtaining unit 110 may directly receive a voltage profile from an external source connected by wire and/or wirelessly.

As another example, the profile obtaining unit 110 may receive battery information about the battery voltage and voltage measurement time points. Then, the profile obtaining unit 110 may generate a voltage profile based on the received battery information. That is, the profile obtaining unit 110 may obtain a voltage profile by directly generating the voltage profile based on the battery information.

The voltage section determining step (S200) is a step of determining a first voltage section and a second voltage section from the plurality of voltage profiles obtained in the voltage profile obtaining step (S100), and may be performed by the control unit 120.

First, the control unit 120 may determine a reference voltage section for a plurality of voltage profiles. In addition, the control unit 120 may be configured to classify the reference voltage section into a first voltage section and a second voltage section.

Specifically, the control unit 120 may be configured to classify the reference voltage section into a low voltage section and a high voltage section. The reference voltage section may be classified into a low voltage section and a high voltage section based on the voltage contained within the section. In addition, the control unit 120 may be configured to set the low voltage section as the first voltage section and set the high voltage section as the second voltage section.

The voltage number determining step (S300) is a step of determining a first voltage number of voltages included in the first voltage section and a second voltage number of voltages included in the second voltage section in each of the plurality of voltage profiles, and may be performed by the control unit 120.

Specifically, the control unit 120 may determine the first voltage number by counting the number of times the voltage is measured in the first voltage section. In addition, the control unit 120 may determine the second voltage number by counting the number of times the voltage is measured in the second voltage section. For example, if a voltage is measured at the upper limit of the first voltage section (the lower limit of the second voltage section), this voltage may be included in both the first voltage number and the second voltage number.

The diagnosing step (S400) is a step for diagnosing the state of the battery based on a first ratio of the plurality of first voltage numbers and a second ratio of the plurality of second voltage numbers, and may be performed by the control unit 120.

Specifically, the control unit 120 may calculate a first ratio for each of the plurality of first voltage numbers based on the first reference number, and may calculate a second ratio for each of the plurality of second voltage numbers based on the second reference number. In addition, the control unit 120 may diagnose the state of the battery as a normal state, a warning state, or an abnormal state based on the result of comparing the first ratio and the second ratio.

For example, the control unit 120 may be configured to diagnose the state of the battery as a normal state if the first ratio is greater than the second ratio.

As another example, the control unit 120 may diagnose the state of the battery as a warning state or an abnormal state if the first ratio is lower than or equal to the second ratio. Specifically, the control unit 120 may be configured to diagnose the state of the battery as a warning state if the first change rate and the second change rate are lower than or equal to the reference change rate. Conversely, the control unit 120 may be configured to diagnose the state of the battery as an abnormal state if the first change rate and the second change rate exceed the reference change rate.

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

Another embodiment of the present disclosure may provide a computer-readable storage medium on which a program for performing the various embodiments described above on a computer is recorded.

The program may be implemented as hardware components, software components, and/or a combination of hardware components and software components. The program may be executed by any system capable of executing computer-readable instructions.

Software may include computer programs, codes, instructions, or a combination thereof, which may configure a processing device to perform a desired operation or may independently or collectively command a processing device.

The software may be implemented as a computer program including instructions stored on a computer-readable storage medium. Examples of the computer-readable storage medium include magnetic storage media (e.g., read-only memory (ROM), random-access memory (RAM), floppy disks, hard disks, etc.) and optical reading media (e.g., CD-ROM, DVD (Digital Versatile Disc)). The computer-readable storage medium may be distributed across network-connected computer systems so that the computer-readable codes may be stored and executed in a distributed manner. The storage medium may be readable by a computer, stored in a memory, and executed by a processor.

A computer-readable storage medium may be provided in the form of a non-transitory storage medium. Here, the term ‘non-transitory storage medium’ simply means that it is a tangible device and does not contain signals (e.g., electromagnetic waves), and this term does not distinguish between cases where data is stored semi-permanently on the storage medium and cases where data is stored temporarily. For example, the ‘non-transitory storage medium’ may include a buffer in which data is temporarily stored.

Additionally, the program may be provided as part of a computer program product. The computer program product may be traded between sellers and buyers as a commodity.

A computer program product may include a software program, and a computer-readable storage medium storing the software program. For example, the computer program product may include a product in the form of a software program (e.g., a downloadable application) distributed electronically by a manufacturer of an electronic device or through an electronic market. For electronic distribution, at least a portion of the software program may be stored on a storage medium or temporarily generated. In this case, the storage medium may be a storage medium of a server of a manufacturer of an electronic device, a server of an electronic market, or a relay server that temporarily stores the software program.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### EXPLANATION OF SYMBOLS

10: battery pack
11: battery
12: measuring unit
100: battery diagnosis apparatus
110: profile obtaining unit
120: control unit
130: storage unit

1. A battery diagnosis apparatus, comprising:
a profile obtaining unit configured to obtain a plurality of voltage profiles for a voltage of a battery measured according to a plurality of preset measurement cycles; and
a control unit configured to determine a first voltage section and a second voltage section from the plurality of voltage profiles obtained by the profile obtaining unit in the plurality of preset measurement cycles, determine a plurality of first voltage numbers of voltages included in the first voltage section and a plurality of second voltage numbers of voltages included in the second voltage section in each of the plurality of voltage profiles, and diagnose a state of the battery based on a first ratio of the plurality of first voltage numbers and a second ratio of the plurality of second voltage numbers.

2. The battery diagnosis apparatus according to claim 1,
wherein the control unit is configured to compare the first ratio with the second ratio as a first comparison result, and diagnose the state of the battery as a normal state, a warning state, or an abnormal state based on the first comparison result.

3. The battery diagnosis apparatus according to claim 2,
wherein the control unit is configured to diagnose the state of the battery as the normal state when the first ratio is greater than the second ratio.

4. The battery diagnosis apparatus according to claim 2,
wherein when the first comparison result is that the first ratio is lower than or equal to the second ratio, the control unit is configured to compare a first change rate of the first ratio and a second change rate of the second ratio with a preset reference change rate as a second comparison result, and diagnose the state of the battery as the warning state or the abnormal state based on the second comparison result.

5. The battery diagnosis apparatus according to claim 4,
wherein the control unit is configured to:
diagnose the state of the battery as the warning state when the first change rate and the second change rate are lower than or equal to the preset reference change rate, and
diagnose the state of the battery as the abnormal state when the first change rate and the second change rate exceed the preset reference change rate.

6. The battery diagnosis apparatus according to claim 1,
wherein the control unit is configured to set a reference voltage section in the plurality of voltage profiles and classify the reference voltage section into the first voltage section and the second voltage section.

7. The battery diagnosis apparatus according to claim 6,
wherein the control unit is configured to classify the reference voltage section into a low voltage section and a high voltage section, set the low voltage section as the first voltage section, and set the high voltage section as the second voltage section.

8. The battery diagnosis apparatus according to claim 6,
wherein the control unit is configured to exclude a voltage profile, which does not include a voltage for at least a part of the reference voltage section, among the plurality of voltage profiles from diagnosing the state of the battery.

9. The battery diagnosis apparatus according to claim 6,
wherein the control unit is configured to set a preset voltage section or a common voltage section of the plurality of voltage profiles as the reference voltage section.

10. The battery diagnosis apparatus according to claim 9,
wherein the control unit is configured to:
set the common voltage section as the reference voltage section when the common voltage section of the plurality of voltage profiles exists, and
set the preset voltage section as the reference voltage section when the common voltage section does not exist.

11. The battery diagnosis apparatus according to claim 1,
wherein the control unit is configured to calculate the first ratio for each of the plurality of first voltage numbers based on a first reference number, and calculate the second ratio for each of the plurality of second voltage numbers based on a second reference number.

12. The battery diagnosis apparatus according to claim 11,
wherein the control unit is configured to set a first voltage number for an initial cycle among the plurality of preset measurement cycles as the first reference number, and set a second voltage number for the initial cycle as the second reference number.

13. The battery diagnosis apparatus according to claim 1,
wherein the control unit is configured to diagnose the state of the battery based on a cycle that is greater than or equal to a preset reference cycle among the plurality of preset measurement cycles.

14. A battery pack, comprising the battery diagnosis apparatus according to claim 1.

15. A battery diagnosis method, comprising:
a voltage profile obtaining step of obtaining a plurality of voltage profiles for a voltage of a battery measured according to a plurality of preset measurement cycles;
a voltage section determining step of determining a first voltage section and a second voltage section from the plurality of voltage profiles obtained in the voltage profile obtaining step;
a voltage number determining step of determining a plurality of first voltage numbers of voltages included in the first voltage section and a plurality of second voltage numbers of voltages included in the second voltage section in each of the plurality of voltage profiles; and
a diagnosing step of diagnosing a state of the battery based on a first ratio of the plurality of first voltage numbers and a second ratio of the plurality of second voltage numbers.

16. The battery diagnosis apparatus according to claim 1,
wherein the profile obtaining unit is configured to obtain the plurality of voltage profiles during charging of the battery.

17. The battery diagnosis apparatus according to claim 4,
wherein the control unit is configured to generate a regression model of a profile representing the first ratio for each of the plurality of preset measurement cycles, and set a change rate of the regression model as the first change rate.

18. The battery diagnosis apparatus according to claim 1,
wherein the control unit is configured to diagnose the state of the battery based on the first ratio reflecting a state of a negative electrode of the battery and the second ratio reflecting a state of a positive electrode of the battery.

19. The battery diagnosis method according to claim 15,
wherein the voltage number determining step comprises counting a voltage measured at an upper limit of the first voltage section in both the plurality of first voltage numbers and the plurality of second voltage numbers.

20. The battery diagnosis method according to claim 15,
wherein the diagnosing step comprises diagnosing the state of the battery as a warning state or an abnormal state when the first ratio is lower than or equal to the second ratio in a preset number of consecutive cycles.
